(19) United States
(12) Patent Application Publication
(10) Pub. No.: US 2026/0213119 A1
(43) Pub. Date: Jul. 23, 2026

(54) HIGH-THROUGHPUT LOAD LOCK CHAMBER

(71) Applicant: ASML Netherlands B.V., Veldhoven (NL)

(72) Inventors: Dongchi YU, San Jose, CA (US); Yi-Chen LIN, San Jose, CA (US); Shao-Wei FU, San Jose, CA (US); Jun-li LIN, San Jose, CA (US); Huan-Yu CHANG, San Jose, CA (US)

(73) Assignee: ASML Netherlands B.V., Veldhoven (NL)

(21) Appl. No.: 19/139,994

(22) PCT Filed: Dec. 6, 2023
(86) PCT No.: PCT/EP2023/084631

§ 371 Date: Jun. 17, 2025

Related U.S. Application Data
(60) Provisional application No. 63/433,702, filed on Dec. 19, 2022.

(51) Int. Cl. H01J 37/18; H01J 37/28

(52) U.S. Cl. CPC H01J 37/18; H01J 37/28; H01J 2237/184

(57) ABSTRACT

An improved vacuum chamber for a system handling a wafer is provided. The vacuum chamber may comprise a top wall wherein at least a portion of an interior surface of the top wall is slanted relative to a side view of the top wall. The vacuum chamber may further comprise a gas vent port coupled to the top wall and a baffle coupled to the vacuum chamber and positioned below the gas vent port, wherein the baffle is configured to reduce turbulence of gas that enters the vacuum chamber via the gas vent port.

### CROSS-REFERENCE TO RELATED APPLICATIONS

This application claims priority of U.S. application 63/433,702 which was filed on Dec. 19, 2022 and which is incorporated herein in its entirety by reference.

### FIELD

The embodiments provided herein disclose a particle beam inspection apparatus, and more particularly, an improved load lock chamber that can be used in a particle beam inspection apparatus.

### BACKGROUND

When manufacturing semiconductor integrated circuit (IC) chips, pattern defects and/or uninvited particles (residuals) inevitably appear on a wafer and/or a mask during fabrication processes, thereby reducing the yield to a great degree. For example, uninvited particles may be troublesome for patterns with smaller critical feature dimensions, which have been adopted to meet the increasingly more advanced performance requirements of IC chips.

Pattern inspection tools with a charged particle beam have been used to detect defects or uninvited particles. These tools typically employ a scanning electron microscope (SEM). In the SEM, a beam of primary electrons having a relatively high energy is decelerated to land on a sample at a relatively low landing energy and is focused to form a probe spot thereon. Due to this focused probe spot of primary electrons, secondary electrons will be generated from the surface. By scanning the probe spot over the sample surface and collecting the secondary electrons, pattern inspection tools may obtain an image of the sample surface.

During operation of an inspection tool, the wafer is typically held by a wafer stage in a main chamber. The inspection tool may comprise a wafer positioning device for positioning the wafer stage and wafer relative to the e-beam. This may be used to position a target area on the wafer, i.e., an area to be inspected, in an operating range of the e-beam. During inspection, the main chamber is maintained in a deep vacuum state. The inspection tool may also comprise a small vacuum chamber called a load lock chamber, which is connected to the large main chamber usually with a gate between the chambers. The load lock chamber is used to transfer wafers between the atmospheric cleanroom environment and the main chamber in a deep vacuum state. A wafer is first loaded into the load lock chamber while at atmosphere. The load lock chamber is then pumped down to a high vacuum pressure. The gate connecting to the main chamber is then opened, and the wafer is then mechanically transferred into the main chamber. After the wafer is processed or inspected, it is transferred back to the load lock chamber, and then the load lock chamber is vented up to the atmospheric level. During this process the main chamber is always maintained in a high vacuum state. A load lock chamber allows wafers to be transferred into and out of the main chamber without venting the main chamber to atmosphere.

### SUMMARY

The embodiments provided herein disclose a charged-particle beam apparatus, and more particularly an improved load lock chamber.

One aspect of the present disclosure is directed to a vacuum chamber for a system configured to handle a wafer. The vacuum chamber may include a top wall wherein at least a portion of an interior surface of the top wall is slanted relative to a side view of the top wall. The vacuum chamber may further include a gas vent port coupled to the top wall and a baffle coupled to the vacuum chamber and positioned below the gas vent port, wherein the baffle is configured to reduce turbulence of gas that enters the vacuum chamber via the gas vent port.

Another aspect of the present disclosure is directed to a vacuum chamber comprising a top wall having an interior surface facing towards an inside of the vacuum chamber. The vacuum chamber may further comprise a gas vent port coupled to the top wall and configured to provide gas into the vacuum chamber. At least a portion of the interior surface of the top wall is sloped away at a downward angle from a position of the gas vent port and the vacuum chamber is configured to receive a wafer and hold the wafer on a wafer stage.

Other advantages of the present invention will become apparent from the following description taken in conjunction with the accompanying drawings wherein are set forth, by way of illustration and example, certain embodiments of the present invention.

### BRIEF DESCRIPTION OF FIGURES

The above and other aspects of the present disclosure will become more apparent from the description of exemplary embodiments, taken in conjunction with the accompanying drawings.

FIG. 1A is a schematic diagram illustrating an exemplary charged particle beam inspection system, consistent with embodiments of the present disclosure.

FIG. 1B is a schematic diagram illustrating an exemplary wafer loading sequence in the charged particle beam inspection system of FIG. 1A, consistent with embodiments of the present disclosure.

FIG. 2 is a schematic diagram illustrating a load lock chamber with a conventional configuration.

FIGS. 3A, 3B, and 3C are schematic diagrams illustrating an exemplary load lock chamber, consistent with embodiments of the present disclosure.

FIGS. 4A and 4B are schematic diagrams illustrating additional exemplary configurations of a load lock chamber, consistent with embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the invention as recited in the appended claims.

Electronic devices are constructed of circuits formed on a piece of silicon called a substrate. The semiconductor material may include, for example, silicon, gallium arsenide, indium phosphide, or silicon germanium, or the like. Many circuits may be formed together on the same piece of silicon and are called integrated circuits or ICs. The size of these circuits has decreased dramatically so that many more of them can fit on the substrate. For example, an IC chip in a smartphone can be as small as a thumbnail and yet may include over 10 billion transistors, the size of each transistor being less than 1/1000th the size of a human hair.

Making these ICs with so many extremely small transistors is a complex, time-consuming, and expensive process, often involving hundreds of individual manufacturing steps. Errors in even one step have the potential to result in defects in the finished IC rendering it useless. Thus, one goal of the manufacturing process is to avoid such defects to maximize the number of functional ICs made in the process, that is, to improve the overall yield of the process.

One component of improving yield is monitoring the chip making process to ensure that it is producing a sufficient number of functional ICs. One way to monitor the process is to inspect the chip circuit structures at various stages of their formation. Inspection can be carried out using an inspection tool such as, for example, a scanning charged-particle microscope (SCPM). For example, an SCPM may be a scanning electron microscope (SEM). An SEM can be used to create the images of these extremely small structures, in effect, taking a “picture” of the structures. The images can be used to determine if the structure was formed properly and also if it was formed in the proper location. If the structure is defective, then the process can be adjusted so the defect is less likely to occur again.

While high process yield is desirable in an IC chip manufacturing facility, it is also essential to maintain a high wafer throughput, defined as the number of wafers processed per hour. High process yields and high wafer throughput can be impacted by the presence of defects, especially when those defects necessitate an operator intervention for a closer review. Thus, high throughput detection and identification of micro and nano-sized defects by inspection tools (such as an SEM) is essential for maintaining high yields and low cost.

For higher throughput and image quality, the main inspection chamber is maintained in a deep vacuum state throughout the operation to allow the particle beams, such as electrons, to travel within the main chamber unimpeded, and also to prevent electrical discharge in the gun assembly (e.g., arcing). The inspection tool may comprise a small vacuum chamber called a load lock chamber, which is connected to the large main chamber. The load lock chamber is used to transfer wafers between the atmospheric cleanroom environment and the main chamber in a deep vacuum state. For example, to transfer a wafer into the main chamber for inspection, the wafer is first loaded into the load lock chamber, which is then depressurized to match the vacuum level of the main chamber. The gate connecting between the load lock chamber and the main chamber is then opened, and the wafer is mechanically transferred into the main chamber. After inspection, the wafer is again placed back in the load lock chamber which is still at the same vacuum level as the main chamber, the gate is closed, and then gas is vented to the load lock chamber to restore the pressure of the chamber to the atmospheric level.

One aspect of the present disclosure includes an improved load lock chamber that increases the throughput of the overall inspection system. The improved load lock system prepares a wafer in a manner that speeds up the inspection process and reduces the chance of introducing an uninvited particle, when compared to conventional particle beam inspection systems. The improved load lock system also provides unobstructed view of the wafer for the various built-in tools (e.g., sensors and vacuum tools), and thus increasing overall adjustability of the inspection system.

For example, a conventional load lock chamber is equipped with a large baffle configured to direct the flow of venting gas. The baffle is typically larger than the wafer to protect the whole surface of the wafer from contamination that may result from the venting gas flow. This large baffle, however, requires a large internal volume of the load lock chamber, which results in longer time for pumping down (i.e., remove gas molecules to reach high-vacuum level) and venting up (i.e., vent gas into the chamber to get to the atmospheric level) the chamber. In addition, because the large baffle is place right between the top wall of the chamber and the wafer, it obscures the wafer from various tools positioned at the top wall, such as laser/infra-red sensors and vacuum tools, and therefore limits the useability of such tools. The improved load lock chamber has a redesigned structure that allows a smaller load lock chamber. It further allows unobstructed view of the wafer for the various built-in tools (e.g., sensors and vacuum tools) on the top of the load lock chamber.

Relative dimensions of components in drawings may be exaggerated for clarity. Within the following description of drawings the same or like reference numbers refer to the same or like components or entities, and only the differences with respect to the individual embodiments are described. As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

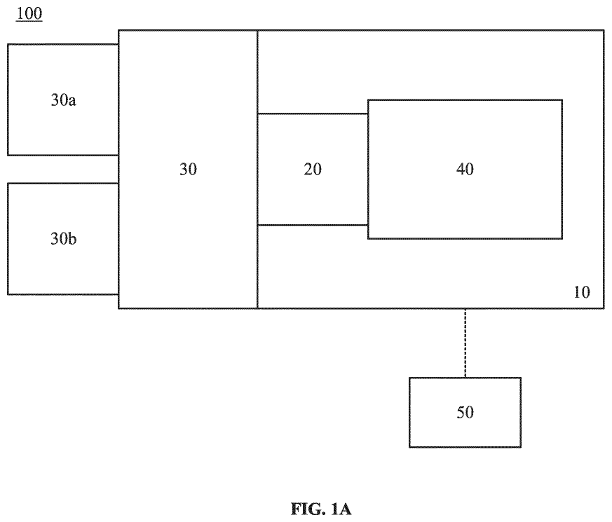

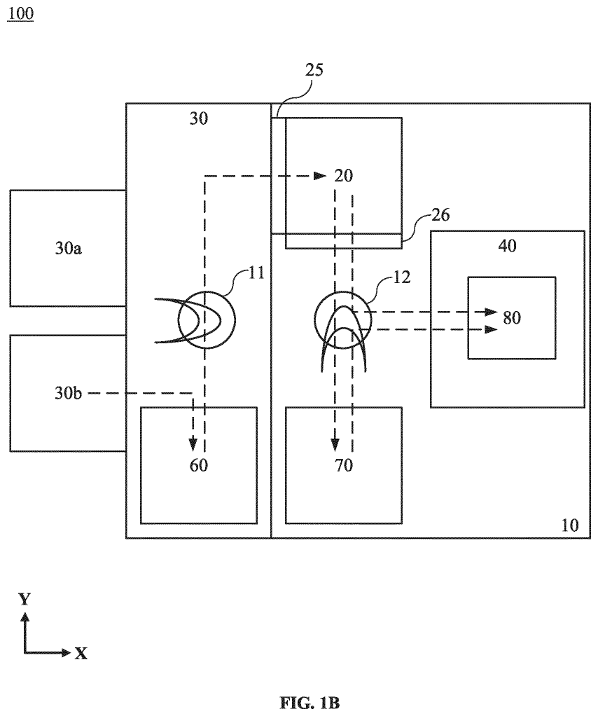

Reference is now made to FIG. 1A, which is a schematic diagram illustrating an exemplary charged particle beam inspection system 100, consistent with embodiments of the present disclosure. As shown in FIG. 1A, charged particle beam inspection system 100 includes a main chamber 10, a load lock chamber 20, an electron beam tool 40, and an equipment front end module (EFEM) 30.

Electron beam tool 40 is located within main chamber 10. While the description and drawings are directed to an electron beam, it is appreciated that the embodiments are not used to limit the present invention to specific charged particles. It is further appreciated that electron beam tool 40 can be a single-beam tool that utilizes a single electron beam or a multi-beam tool that utilizes multiple electron beams.

EFEM 30 includes a first loading port 30a and a second loading port 30b. EFEM 30 may include additional loading port(s). First loading port 30a and second loading port 30b may, for example, receive wafer front opening unified pods (FOUPs) that contain wafers (e.g., semiconductor wafers or wafers made of other material(s)) or samples to be inspected (wafers and samples are collectively referred to as “wafers” hereafter). One or more robot arms (e.g., the robotic arms shown in FIG. 1B) in EFEM 30 transport the wafers to load lock chamber 20.

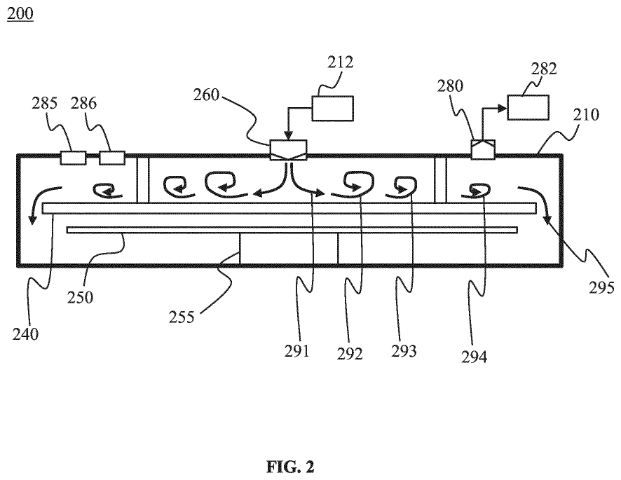

Although FIG. 1A shows that load lock chamber 20 is located within main chamber 10, it is further appreciated that load lock chamber 20 may be located next to main chamber 10 abutting against the outside of the main chamber as shown in FIG. 2.

Load lock chamber 20 may be attached to main chamber 10 with a gate (e.g., gate 26 of FIG. 1B) between the chambers. Load lock chamber 20 may include a sample holder (e.g., wafer stage 255 of FIG. 2) that can hold one or more wafers. Load lock chamber 20 may also include a mechanical transfer apparatus (e.g., robot arm 12 of FIG. 1B) to move wafers to and from main chamber 10.

Load lock chamber 20 may be connected to a load lock vacuum pump system (e.g., a vacuum port 280 of FIG. 2), which removes gas molecules in load lock chamber 20 to reach a first pressure below the atmospheric pressure. After reaching the first pressure, one or more robot arms (shown in FIG. 1B) transport the wafer from load lock chamber 20 to main chamber 10. In some embodiments, main chamber 10 may also be connected to its own vacuum pump system (not shown), which removes gas molecules in main chamber 10 to reach a second pressure corresponding to a deeper vacuum state than the first pressure. After reaching the second pressure, the wafer is subject to inspection by electron beam tool 40.

A controller 50 is electronically connected to electron beam tool 40. Controller 50 may be a computer configured to execute various controls of charged particle beam inspection system 100.

While controller 50 is shown in FIG. 1A as being outside of the structure that includes main chamber 10, load lock chamber 20, and EFEM 30, it is appreciated that controller 50 may be part of the structure. While the present disclosure provides examples of main chamber 10 housing an electron beam inspection tool, it should be noted that aspects of the disclosure in their broadest sense are not limited to a chamber housing an electron beam inspection tool. Rather, it is appreciated that the foregoing principles may also be applied to other tools that operate under the second pressure.

In some embodiments, controller 50 may include one or more processors (not shown). A processor may be a generic or specific electronic device capable of manipulating or processing information. For example, the processor may include any combination of any number of a central processing unit (or “CPU”), a graphics processing unit (or “GPU”), an optical processor, a programmable logic controllers, a microcontroller, a microprocessor, a digital signal processor, a hardware accelerator, an intellectual property (IP) core, a Programmable Logic Array (PLA), a Programmable Array Logic (PAL), a Generic Array Logic (GAL), a Complex Programmable Logic Device (CPLD), a Field-Programmable Gate Array (FPGA), a System On Chip (SoC), an Application-Specific Integrated Circuit (ASIC), and any type circuit capable of data processing. The processor may also be a virtual processor that includes one or more processors distributed across multiple machines or devices coupled via a network.

In some embodiments, controller 50 may further include one or more memories (not shown). A memory may be a generic or specific electronic device capable of storing codes and data accessible by the processor (e.g., via a bus). For example, the memory may include any combination of any number of a random-access memory (RAM), a read-only memory (ROM), an optical disc, a magnetic disk, a hard drive, a solid-state drive, a flash drive, a security digital (SD) card, a memory stick, a compact flash (CF) card, or any type of storage device. The codes and data may include an operating system (OS) and one or more application programs (or “apps”) for specific tasks. The memory may also be a virtual memory that includes one or more memories distributed across multiple machines or devices coupled via a network.

Reference is now made to FIG. 1B, which is a schematic diagram illustrating an exemplary wafer loading sequence in charged particle beam inspection system 100 of FIG. 1A, consistent with embodiments of the present disclosure. FIG. 1B is a two-dimensional view from the top of inspection system 100. The X and Y axes represent two perpendicular directions defining the projection plane. In some embodiments, charged particle beam inspection system 100 may include a robot arm 11 located in EFEM 30 and a robot arm 12 located in main chamber 10. In some embodiments, EFEM 30 may also include a pre-aligner 60 configured to position a wafer accurately before transporting the wafer to load lock chamber 20.

In some embodiments, first loading port 30a and second loading port 30b, for example, may receive wafer front opening unified pods (FOUPs) that contain wafers. Robot arm 11 in EFEM 30 may transport the wafers from any of the loading ports to pre-aligner 60 for assisting with the positioning. Pre-aligner 60 may use mechanical or optical aligning methods to position the wafers. After pre-alignment, robot arm 11 may transport one or more wafers to load lock chamber 20 through gate 25.

After the wafers are transported to load lock chamber 20, a load lock vacuum pump (not shown) may remove gas molecules in load lock chamber 20 to reach a first pressure below the atmospheric pressure. After reaching the first pressure, gate 26 connecting between the load lock chamber and the main chamber is opened, and a robot arm 12 may transport the wafer from load lock chamber 20 to a wafer stage 80 of electron beam tool 40 in main chamber 10. In some embodiments, main chamber 10 may also be connected to a main chamber vacuum pump system (not shown), which may further remove gas molecules in main chamber 10 to reach a second pressure below the first pressure. After reaching the final pressure, the wafer may be subject to inspection by electron beam tool.

After inspection, the wafer is transported back to load lock chamber 20 which is still at the same vacuum level as main chamber 10. And then, gate 26 is closed and gas is vented into load lock chamber 20 to restore the pressure of the chamber to the atmospheric level. When the pressure within load lock chamber 20 reaches the atmospheric level, gate 25 is opened and the inspected wafer is swapped with a new wafer.

In some embodiments, main chamber 10 may include a parking station 70 configured to temporarily store a wafer before inspection. For example, when the inspection of a first wafer is completed, the first wafer may be unloaded from wafer stage 80, and then a robot arm 12 may transport a second wafer from parking station 70 to wafer stage 80. Afterwards, robot arm 12 may transport a third wafer from load lock chamber 20 to parking station 70 to store the third wafer temporarily until the inspection for the second wafer is finished. Parking station 70 may also be maintained in a high vacuum state.

Reference is now made to FIG. 2, which is a schematic diagram illustrating a load lock chamber 200 with a conventional configuration. In a conventional design, the top portion of load lock chamber 200 is sealed with a flat top wall 210. Various tools and structures are placed on the flat top wall 210. For example, load lock chamber 200 may have a vacuum port 280 that is connected to pumping-down structures 282, which may comprise a load lock roughing valve, a turbomolecular pump, and/or a load lock roughing pump. Load lock chamber 200 may also include a gas vent port 260 that is connected to gas venting structures 212, which may include a gas supply and a gas vent valve. Load lock chamber 200 also includes a wafer stage 255 to hold a wafer 250 during pumping-down and venting-up operations.

In a conventional load lock chamber design, gas vent port 260 is typically placed on flat top wall 210, and accordingly the vented gas flows from top to bottom as illustrated by arrow 291. Injecting gas from the top of load lock chamber 20 provides a strong downward gas flow within the chamber, which enables fast venting-up operation for better system throughput. Downward gas venting flow also reduces the chance of disturbing contaminant particles that may present on the bottom interior surface of load lock chamber 20.

Downward gas flow, however, requires a large baffle 240 to protect wafer 250. For example, baffle 240 is usually hung immediately below gas vent port 260 to prevent the high-speed downward gas flow from impinging the surface of wafer 250 directly. Instead, the downward gas flow is redirected sideways as illustrated by arrows 291-295. The high-speed impinging gas flow may also create vortical gas flows shown as arrows 292, 293, and 294 and strong local flow separations—i.e., the gas flow directions are locally reversed. As illustrated by arrows 292, 293, and 294, these vortical gas flows and local flow separations propagate for a long distance over the surface of baffle 240 with strong disturbing motions, which can stir up particles (not shown) along the way. The strong disturbing gas flow and the stirred-up particles may affect wafer 250, and resulting in defects, decreased throughput, and lower inspection quality. Therefore, baffle 240 in load lock chamber 200 with flat top wall 210 is typically very large to ensure that the vortical flows and local flow separations are sufficiently attenuated or eliminated (as illustrated by arrows 292, 293, 294, and 295) before reaching the surface of wafer 250.

Installing a large baffle in load lock chamber has disadvantages. First, just to accommodate such a large baffle within the chamber, the load lock chamber needs to have a large internal volume. A large internal volume, however, means that it takes longer to pump-down and vent-up the chamber, and accordingly reduces the overall throughput of the system. Second, a large baffle obscures the view of the wafer surface from various tools if the tools are installed on the top wall of the load lock chamber. For example, as shown in FIG. 2, load lock chamber 200 may include sensors 285 on top wall 210. Sensors 285 may comprise, but not limited to, a laser-based wafer positioning sensor, an infrared sensor, a temperature sensor. Load lock chamber 200 may also have vacuum qualifying tools 286 on top wall 210, which includes but not limited to a plasma cleaner and a residual gas analyzer. Sensors 285 and vacuum qualifying tools 286 require an unobstructed direct line of sight to the surface of wafer 250 to work properly. Large baffle 240 renders sensors 285 and vacuum qualifying tools 286 unusable, or at least limits their placement options. Lastly, a large baffle may also degrade the efficiency of the pumping-down operation. A load lock chamber may have a vacuum port 280 installed on top wall 210. As shown in FIG. 2, large baffle 240 blocks the opening of vacuum port 280, and therefore the pumping speed of vacuum pumps (not shown) could be limited.

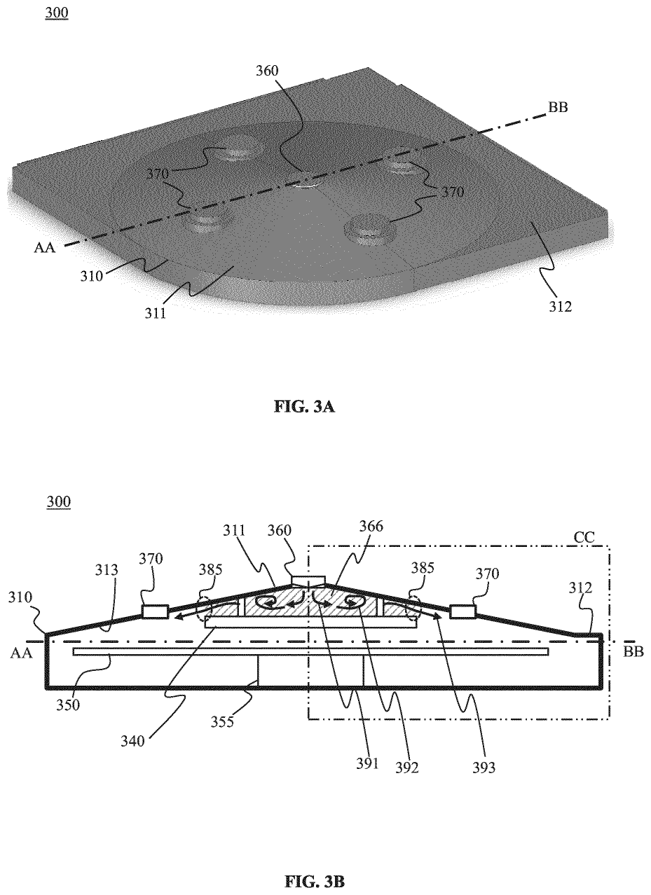

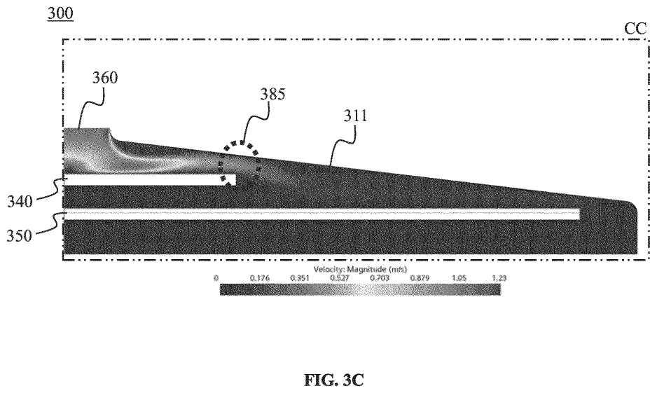

Reference is now made to FIGS. 3A, 3B, and 3C, which are schematic diagrams illustrating an exemplary load lock chamber 300, consistent with embodiments of the present disclosure. FIG. 3A is a perspective view of load lock chamber 300. Load lock chamber 300 may include a top wall 310 which is slanted relative to a side view top wall 310, i.e., top wall 310 slopes away at a downward angle towards side walls of load lock chamber 300. In some embodiments, the whole portion of top wall 310 is slanted, while in other embodiments only a portion of top wall 310 is slanted such that it comprises a slanted top section 311 and a flat top section 312. In some embodiments, slanted top section 311 of top wall 310 may be a cone shape. Load lock chamber 300 may further include a gas vent port 360 located substantially close to a vertex of the cone shaped slanted top section 311. In some embodiments, load lock chamber 300 may further include one or more of reserved ports 370. Some of reserved ports 370 may be placed within slanted top section 311, but away from gas vent port 360. Although FIG. 3A illustrates that slanted top section 311 of top wall 310 is a cone shape, it is appreciated that top wall 310 may include various shapes, including but not limited to a pyramid shape. A pyramid can have three or more sides depending on the base. For example, if the base is a triangle, the pyramid has three sides; if the base is a square, the pyramid has four sides; and so on. A pyramid becomes a cone as the number of sides of its base increases.

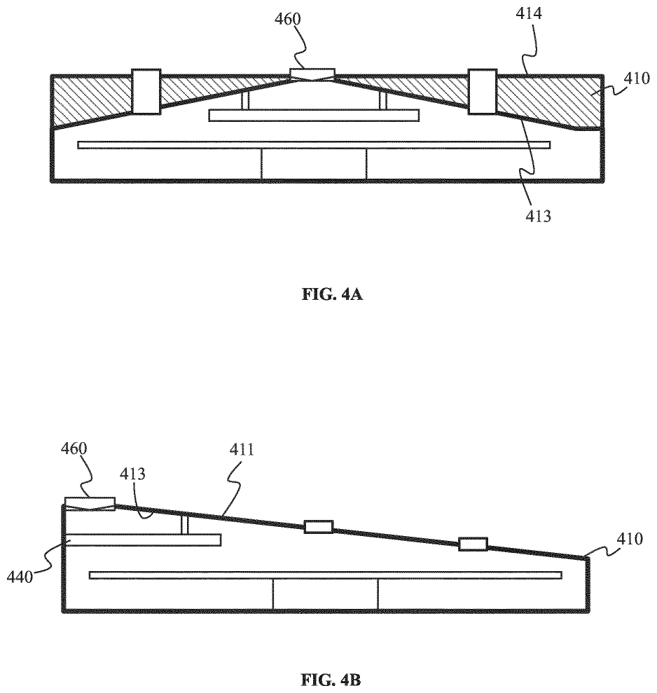

FIG. 3B is a sectional view of the load lock chamber 300 of FIG. 3A. As discussed above, slanted top wall 310 may comprise slanted top section 311 and flat top section 312. A gas vent port 360 is installed close to the vertex (i.e., most elevated point) of slanted top section 311. Although slated top section 311 is illustrated as a cone-shape in FIGS. 3A-3C, it is appreciated that different styles (e.g., a pyramid) of slanted top section could be used (e.g., load lock chambers 400 in FIGS. 4A and 4B). Load lock chamber 300 may further include a wafer stage 355 configured to hold wafer 350 during pumping-down and venting-up operations. As described above with respect to FIG. 2, gas is injected via gas vent port 360 during the venting-up operation, which creates a strong downward gas flow within the chamber. To protect wafer 350 from the strong downward gas flow, a baffle 340 may be positioned (e.g., hung) beneath gas vent port 360. For the reasons explained below, baffle 340 can be much smaller than baffle 240 in FIG. 2.

Because of the slanted top wall, the space created by an interior surface of slanted top section 311 and upper surface of baffle 340 gets narrower going towards the edge of baffle 340. This narrowing space is annotated as 366 with a shade in FIG. 3B. When gas is injected via gas vent port 360, it spreads through narrowing space 366 and exits to the rest of the chamber through a narrow opening 385 around the edge of baffle 340. Narrowing space 366 and narrow opening 385 may effectively suppress forementioned vortical flows and local separations, even with much smaller baffle 340. For example, as illustrated in FIG. 3B, the strong downward gas flow 391 may create a vortex gas flow 392. But, by the time gas flow reaches the edge of baffle 340, the vortex motion is sufficiently attenuated or eliminated, which results in a smooth gas flow exiting through narrow opening 385. FIG. 3C illustrates the velocity of gas flow in the chamber. The velocity of gas flow is very high around gas vent port 360. The velocity, however, gets attenuated rapidly as gas flows through narrowing space 366, and when gas flow arrives around narrow opening 385, the velocity becomes substantially low. Such slow gas flow may not affect wafer 350 even if the gas moves downward and hits the surface of wafer 350.

Since the size of baffle 340 is greatly reduced compared to the flat top load lock chamber (such as load lock chamber 200 in FIG. 2), the upper portion of load lock chamber 300 (e.g., the portion above the level of wafer 350) may also be made much smaller, which reduces the internal volume of load lock chamber 300. In some embodiments, the volume reduction could be approximately 30% of total internal volume, which may correspond to approximately 30% of reduction in time required for the venting-up and pumping-down operations.

Furthermore, baffle 340 no longer covers the entire surface of wafer 350, rather it covers only center portion of wafer 350. Therefore, with small baffle 340, reserved ports 370 on slanted top wall 310 have direct and unobstructed line of sight with the surface of wafer 350. Accordingly, various sensors (such as sensors 285 of FIG. 2) and vacuum tools (such as vacuum qualifying tools 286 of FIG. 2) may be connected to reserved ports 370. Similarly, a vacuum pump (e.g., turbomolecular pump or roughing pump) may be connected to one or more of reserved ports 370 enabling fast pumping down speed as there is no blockage by a large baffle.

Reference is now made to FIGS. 4A and 4B, which are schematic diagrams illustrating additional exemplary configurations of a load lock chamber, consistent with embodiments of the present disclosure. As shown in FIG. 4A, a top wall 410 may comprise a flat top surface 414 and a slanted interior surface 413. Flat top surface 414 may provide structural support for various tools that could be installed on top of the load lock chamber, while operating in the same way with the same benefits as load lock chamber 300 with a slanted top wall shown in FIGS. 3A-3C.

FIG. 4B shows another possible configuration of a load lock chamber with a different shape of slanted top wall. The top wall 410 may be slanted only on one side. For example, top wall 410 may have a half-cone shape. A gas vent port 460 may be installed at an apex position of the half-cone shape, as shown in FIG. 4B. It is appreciated that top wall 410 may be in a different shape, such as a half-pyramid shape. The space created by a slanted interior surface 413 and upper surface of baffle 440 gets narrower towards the edge of baffle 440, and accordingly the strong downward gas flow can be mitigated in a similar manner as explained with respect to FIGS. 3A-3C above.

The embodiments may further be described using the following clauses:
1. A vacuum chamber for a system configured to handle a wafer, comprising:
a top wall wherein at least a portion of an interior surface of the top wall is slanted relative to a side view of the top wall;
a gas vent port coupled to the top wall; and
a baffle coupled to the vacuum chamber and positioned below the gas vent port, wherein the baffle is configured to reduce turbulence of gas that enters the vacuum chamber via the gas vent port.
2. The vacuum chamber of clause 1, further comprising a space created by the top wall and the baffle, wherein the space has a maximum height around the gas vent port and gets narrower towards an edge of the baffle.
3. The vacuum chamber of clause 1, wherein the vacuum chamber is configured to receive a wafer and hold the wafer on a wafer stage, wherein the baffle is configured to be positioned between the gas vent port and the wafer when the wafer is held on the wafer stage.
4. The vacuum chamber of clause 3, wherein a maximum width of the baffle is smaller than a diameter of the wafer.
5. The vacuum chamber of clause 3, wherein the baffle has a substantially circular shape, and a diameter of the baffle is smaller than a diameter of the wafer.
6. The vacuum chamber of any of clause 2-5, further comprising a sensor coupled to the top wall, wherein the sensor is positioned to have a direct line of sight to the wafer when the wafer is held on the wafer stage.
7. The vacuum chamber of any of clause 2-6, further comprising a vacuum tool coupled to the top wall, wherein the vacuum tool is positioned to have a direct line of sight to the wafer when the wafer is held on the wafer stage.
8. The vacuum chamber of any of clause 1-7, wherein the interior surface of the top wall has a cone shape or a pyramid shape.
9. The vacuum chamber of any of clause 1-7, wherein the interior surface of the top wall has a half-cone shape or a half-pyramid shape.
10. The vacuum chamber of any of clause 1-9, wherein the gas vent port is located at a peak point of the interior surface of the top wall.
11. A vacuum chamber comprising:
a top wall having an interior surface facing towards an inside of the vacuum chamber; and
a gas vent port coupled to the top wall and configured to provide gas into the vacuum chamber;
wherein at least a portion of the interior surface of the top wall is sloped away at a downward angle from a position of the gas vent port and the vacuum chamber is configured to receive a wafer and hold the wafer on a wafer stage.
12. The vacuum chamber of clause 11, further comprising a baffle coupled to the vacuum chamber and configured to be positioned between the gas vent port and the wafer when the wafer is held on the wafer stage, wherein the baffle is configured to manipulate a flow of the gas provided via the gas vent port.
13. The vacuum chamber of clause 12, further comprising a space created by the interior surface of the top wall and an upper surface of the baffle, wherein the space has a maximum height around the gas vent port and gets narrower towards an edge of the baffle.
14. The vacuum chamber of clause 12, wherein a maximum width of the baffle is smaller than a diameter of the wafer.
15. The vacuum chamber of clause 12, wherein the baffle has a substantially circular shape, and a diameter of the baffle is smaller than a diameter of the wafer.
16. The vacuum chamber any of clause 11-15, further comprising a sensor coupled to the top wall, wherein the sensor is positioned to have a direct line of sight to the wafer when the wafer is held on the wafer stage.
17. The vacuum chamber of any of clause 11-16, further comprising a vacuum tool coupled to the top wall, wherein the vacuum tool is positioned to have a direct line of sight to the wafer when the wafer is held on the wafer stage.
18. The vacuum chamber of any of clause 11-17, wherein the interior surface of the top wall has a cone shape or a pyramid shape.
19. The vacuum chamber of any of clause 11-17, wherein the interior surface of the top wall has a half-cone shape or a half-pyramid shape.
20. The vacuum chamber of any of clause 1-19, wherein the gas vent port is located at a peak point of the interior surface of the top wall.

Although the disclosed embodiments have been explained in relation to the preferred embodiments, it is to be understood that other modifications and variations can be made without departing the spirit and scope of the subject matter as hereafter claimed.

1. A vacuum chamber for a system configured to handle a wafer, comprising:
a top wall wherein at least a portion of an interior surface of the top wall is slanted relative to a side view of the top wall;
a gas vent port coupled to the top wall; and
a baffle coupled to the vacuum chamber and positioned below the gas vent port, wherein the baffle is configured to reduce turbulence of gas that enters the vacuum chamber via the gas vent port.

2. The vacuum chamber of claim 1, further comprising a space created by the top wall and the baffle, wherein the space has a maximum height around the gas vent port and gets narrower towards an edge of the baffle.

3. The vacuum chamber of claim 1, wherein the vacuum chamber is configured to receive a wafer and hold the wafer on a wafer stage, wherein the baffle is configured to be positioned between the gas vent port and the wafer when the wafer is held on the wafer stage.

4. The vacuum chamber of claim 3, wherein a maximum width of the baffle is smaller than a diameter of the wafer.

5. The vacuum chamber of claim 3, wherein the baffle has a substantially circular shape, and a diameter of the baffle is smaller than a diameter of the wafer.

6. The vacuum chamber of claim 2, further comprising a sensor coupled to the top wall, wherein the sensor is positioned to have a direct line of sight to the wafer when the wafer is held on a wafer stage.

7. The vacuum chamber of claim 2, further comprising a vacuum tool coupled to the top wall, wherein the vacuum tool is positioned to have a direct line of sight to the wafer when the wafer is held on a wafer stage.

8. The vacuum chamber of claim 1, wherein the interior surface of the top wall has a cone shape or a pyramid shape.

9. The vacuum chamber of claim 1, wherein the interior surface of the top wall has a half-cone shape or a half-pyramid shape.

10. The vacuum chamber of claim 1, wherein the gas vent port is located at a peak point of the interior surface of the top wall.

11. A vacuum chamber comprising:
a top wall having an interior surface facing towards an inside of the vacuum chamber; and
a gas vent port coupled to the top wall and configured to provide gas into the vacuum chamber;
wherein at least a portion of the interior surface of the top wall is sloped away at a downward angle from a position of the gas vent port and the vacuum chamber is configured to receive a wafer and hold the wafer on a wafer stage.

12. The vacuum chamber of claim 11, further comprising a baffle coupled to the vacuum chamber and configured to be positioned between the gas vent port and the wafer when the wafer is held on the wafer stage, wherein the baffle is configured to manipulate a flow of the gas provided via the gas vent port.

13. The vacuum chamber of claim 12, further comprising a space created by the interior surface of the top wall and an upper surface of the baffle, wherein the space has a maximum height around the gas vent port and gets narrower towards an edge of the baffle.

14. The vacuum chamber of claim 12, wherein a maximum width of the baffle is smaller than a diameter of the wafer.

15. The vacuum chamber of claim 12, wherein the baffle has a substantially circular shape, and a diameter of the baffle is smaller than a diameter of the wafer.

16. The vacuum chamber of claim 11, further comprising a sensor coupled to the top wall, wherein the sensor is positioned to have a direct line of sight to the wafer when the wafer is held on the wafer stage.

17. The vacuum chamber of claim 11, further comprising a vacuum tool coupled to the top wall, wherein the vacuum tool is positioned to have a direct line of sight to the wafer when the wafer is held on the wafer stage.

18. The vacuum chamber of claim 11, wherein the interior surface of the top wall has a cone shape or a pyramid shape.

19. The vacuum chamber of claim 11, wherein the interior surface of the top wall has a half-cone shape or a half-pyramid shape.

20. The vacuum chamber of claim 11, wherein the gas vent port is located at a peak point of the interior surface of the top wall.
